(19) United States
(12) Patent Application Publication
(10) Pub. No.: US 2025/0232961 A1
(43) Pub. Date: Jul. 17, 2025

(54) PLASMA PROCESSING APPARATUS

(71) Applicant: HITACHI HIGH-TECH CORPORATION, Minato-ku, Tokyo (JP)

(72) Inventors: Kazuya TAJIMA, Tokyo (JP); Shunsuke KANAZAWA, Tokyo (JP)

(21) Appl. No.: 18/692,128

(22) PCT Filed: May 31, 2023
(86) PCT No.: PCT/JP2023/020271

§ 371 Date: Mar. 14, 2024

(51) Int. Cl. H01J 37/32; H01L 21/67

(52) U.S. Cl. CPC H01J 37/32697; H01J 37/32541; H01J 37/32568; H01J 37/32834; H01J 2237/3343; H01L 21/67069

(57) ABSTRACT

A plasma processing apparatus 100 includes a discharge chamber 1, a processing chamber 2, and an exhaust chamber 3 that are provided inside a vacuum container 101. A sample stage 4 on which a wafer is placeable is disposed inside the processing chamber 2. A dispersion plate 20 is provided between the processing chamber 2 and the discharge chamber 1. A plurality of through holes 21 are formed in the dispersion plate 20 such that the processing chamber 2 and the discharge chamber 1 communicate with each other. An exhaust plate 30 is provided between the processing chamber 2 and the exhaust chamber 3 in a manner of surrounding the sample stage 4. A plurality of through holes 31 are formed in the exhaust plate 30 such that the processing chamber 2 and the exhaust chamber 3 communicate with each other. An electrode EL1 having a ring shape is attached to the dispersion plate 20, and an electrode EL2 having a ring shape is attached to the exhaust plate 30. Variable DC power supplies are electrically connected to the electrode EL1 and the electrode EL2, respectively.

### TECHNICAL FIELD

The present invention relates to a plasma processing apparatus.

### BACKGROUND ART

In a market of semiconductor devices, in order to reduce power consumption and increase storage capacity, progress has further been made toward a microfabricated device structure and a three-dimensional device structure. In manufacturing a three-dimensional device structure, since the structure is three-dimensional and complicated, in addition to “anisotropic etching processing” in which etching is performed in a vertical direction on a surface of a wafer, “isotropic etching processing” in which etching can also be performed in a horizontal direction is performed.

For example, PTL 1 discloses a plasma processing apparatus capable of performing isotropic etching processing with high accuracy. In order to implement microfabrication through the isotropic etching processing, formation of a reaction layer by radical adsorption and desorption of the reaction layer by being heated are performed. By these manufacturing steps, an etching amount can be controlled to a level of several nm or less.

Specifically, first, a wafer that is an object to be processed is conveyed into a processing chamber in a vacuum container by a conveying mechanism. Next, the wafer is placed on a sample stage having a function of electrostatic adsorption. Next, a plasma is generated in a discharge chamber, and ions and electrons are reduced by a dispersion plate. Thus, particles having relatively high reactivity such as neutral particles and radicals of gas are introduced into the processing chamber. Next, such particles are adsorbed into a surface of a film to be etched, and a reaction layer is formed on the surface of the film by a chemical reaction between the particles and the film (adsorption step).

Next, heat or kinetic energy is applied to the reaction layer to desorb the reaction layer from the surface of the film (desorption step). The adsorption step and the desorption step are alternately repeated at a predetermined period such that etching processing can be selectively performed on the film.

FIG. 4 in PTL 2 discloses a dispersion plate that divides a discharge chamber and a processing chamber, and through holes formed in the dispersion plate. In PTL 2, in order to prevent ions that pass through the through holes from entering a wafer, the through holes are disposed only in an outer peripheral portion of the dispersion plate. The entry of ions into the processing chamber causes a decrease in controllability of an etching amount, accumulation of charges on the sample stage, and the like. During discharge, a large number of ions are distributed in the vicinity of a center of the discharge chamber, and a large number of radicals are distributed in the vicinity of an outer wall of the discharge chamber. Therefore, it is possible to allow the radicals to effectively pass through while significantly preventing the ions from entering the processing chamber.

### CITATION LIST

### Patent Literature

PTL 1: JP2015-185594A
PTL 2: WO2021/124539

### SUMMARY OF INVENTION

### Technical Problem

In the techniques disclosed in PTL 1 and PTL 2, most of the ions can be prevented from entering the sample stage by the dispersion plate that divides the discharge chamber and the processing chamber, but the entry of ions passing through the through holes of the dispersion plate cannot be prevented. Therefore, the ions are non-uniformly incident on the wafer placed on the sample stage, which is one of the reasons for a decrease in uniformity within a surface of the wafer in the etching processing.

For example, it is also considered that the ions are prevented from entering the through holes by using two dispersion plates, but in this case, radicals in an active state supplied into the processing chamber also decrease.

A main object of the present application is to prevent ions from reaching a sample stage without affecting the distribution and supply amount of radicals. Other problems and novel features will be clarified according to the description of the present specification and the accompanying drawings.

### Solution to Problem

An outline of a representative one among embodiments disclosed in the present application will be briefly described as follows.

A plasma processing apparatus according to one embodiment includes: a vacuum container; a processing chamber that is a part of an inside of the vacuum container; a discharge chamber that is a part of the inside of the vacuum container, is provided above the processing chamber, and is configured to generate plasma; an exhaust chamber that is a part of the inside of the vacuum container, is provided below the processing chamber, and is formed with an exhaust port; a sample stage that is disposed inside the processing chamber and on which a wafer is placeable; a dispersion plate provided between the processing chamber and the discharge chamber; a plurality of first through holes formed on the dispersion plate such that the processing chamber and the discharge chamber communicate with each other; an exhaust plate provided between the processing chamber and the exhaust chamber in a manner of surrounding the sample stage; and a plurality of second through holes formed on the exhaust plate such that the processing chamber and the exhaust chamber communicate with each other. A first electrode having a ring shape is attached to the dispersion plate, a second electrode having a ring shape is attached to the exhaust plate, the first electrode is electrically connected to a first variable DC power supply, and the second electrode is electrically connected to a second variable DC power supply.

### Advantageous Effects of Invention

According to one embodiment, it is possible to prevent the ions from reaching the sample stage without affecting the distribution and supply amount of the radicals.

### BRIEF DESCRIPTION OF DRAWINGS

FIG. 1 is a schematic cross-sectional view illustrating a plasma processing apparatus according to Embodiment 1.

FIG. 2 is a bottom view illustrating a dispersion plate in Embodiment 1.

FIG. 3 is a plan view illustrating an exhaust plate in Embodiment 1.

FIG. 4 is a schematic cross-sectional view illustrating trajectories of ions passing through the dispersion plate according to Embodiment 1.

### DESCRIPTION OF EMBODIMENTS

Hereinafter, an embodiment will be described in detail with reference to the drawings. In all the drawings for describing the embodiment, members having the same function are denoted by the same reference numerals, and the repeated description thereof is omitted. In the following embodiment, a description of the same or similar parts will not be repeated in principle unless particularly necessary.

### Embodiment 1

### <Configuration of Plasma Processing Apparatus>

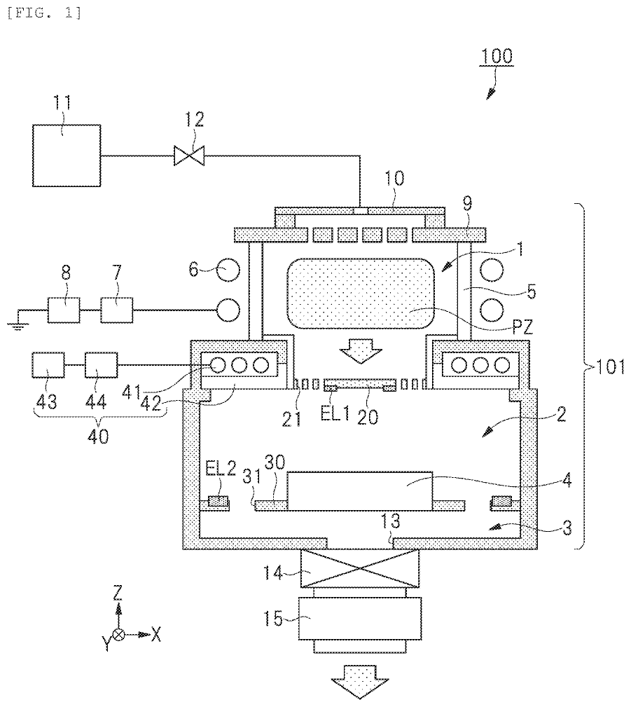

Hereinafter, a plasma processing apparatus 100 according to Embodiment 1 will be described with reference to FIG. 1.

As illustrated in FIG. 1, the plasma processing apparatus 100 includes a vacuum container 101. Each of a discharge chamber 1, a processing chamber 2, and an exhaust chamber 3 constitutes a part of an inside of the vacuum container 101. The discharge chamber 1 for generating a plasma PZ is provided above the processing chamber 2. The exhaust chamber 3 is provided below the processing chamber 2. A bottom portion of the exhaust chamber 3 is formed with an exhaust port 13. Each of the discharge chamber 1, the processing chamber 2, and the exhaust chamber 3 has a cylindrical shape, and central axes thereof are disposed at positions that are coaxial or approximately coaxial with each other. The discharge chamber 1 is implemented by a cylindrical ceramic chamber 5.

A sample stage 4 on which a wafer as an object to be processed can be placed is provided inside the processing chamber 2. The sample stage 4 has a function of fixing the wafer on an upper surface thereof by electrostatic adsorption. The wafer includes a semiconductor substrate in which a p-type or n-type impurity region is formed, a semiconductor element such as a transistor formed on the semiconductor substrate, and a wiring layer formed on the semiconductor element. The wafer according to Embodiment 1 is a wafer in a state where these are in the middle of manufacture.

A dispersion plate 20 is provided between the processing chamber 2 and the discharge chamber 1. The dispersion plate 20 is made of, for example, a ceramic material. A plurality of through holes 21 are formed in the dispersion plate 20 such that the processing chamber 2 and the discharge chamber 1 communicate with each other. Each of the sample stage 4 and the dispersion plate 20 has a circular planar shape. Central axes of the sample stage 4 and the dispersion plate 20 are disposed at positions that are coaxial or approximately coaxial with the central axes of the discharge chamber 1, the processing chamber 2, and the exhaust chamber 3.

An electrode EL1 is attached to a lower surface of the dispersion plate 20. The electrode EL1 has a ring shape coaxial with the dispersion plate 20. Alumite processing is performed on a surface of the electrode EL1 to prevent the electrode EL1 from being directly exposed to the plasma PZ. The electrode EL1 may also be incorporated in the dispersion plate 20. In this case, the alumite processing may not be performed.

An ICP coil 6 is provided outside the discharge chamber 1. The ICP coil 6 is connected to a radio-frequency power supply 8 via a matching device 7 and generates the plasma PZ by an ICP discharge method. A frequency band of several tens of MHz such as 13.56 MHz is used for a frequency of radio-frequency power.

A top plate 10 is provided above the discharge chamber 1. A gas dispersion plate 9 having a plurality of through holes is provided below the top plate 10. Processing gas supplied from a processing gas supply unit 11 is introduced into the discharge chamber 1 via the gas dispersion plate 9. A seal member, such as an O-ring, is interposed between the top plate 10 and an upper end portion of a side wall of the discharge chamber 1. Accordingly, an inside of the discharge chamber 1 is hermetically sealed.

A supply flow rate of the processing gas supplied from the processing gas supply unit 11 is adjusted by a mass flow controller 12 provided for each gas type. The processing gas is, for example, a combustible gas, an oxidizing gas, or a mixed gas of the combustible gas and the oxidizing gas. The mixed gas may be diluted with an inert gas.

An IR lamp unit 40 for heating the wafer and an inside of the processing chamber 2 is provided above the processing chamber 2. The IR lamp unit 40 includes a lamp 41 for heating the wafer, a light transmission window 42 made of quartz, a lamp power supply 43, and a radio-frequency cut filter 44.

The lamp 41 is provided above the sample stage 4 and is electrically connected to the lamp power supply 43 via the radio-frequency cut filter 44. The radio-frequency cut filter 44 is provided to prevent noise of radio-frequency power applied to the ICP coil 6 from flowing into the lamp power supply 43. Light emitted from the lamp 41 is light (IR light) mainly ranging from visible light to infrared light. Such IR light can pass through the light transmission window 42, and the wafer and the inside of the processing chamber 2 are heated by the IR light.

Here, a plurality of lamps 41 (three lamps in FIG. 1) are provided. The plurality of lamps 41 are disposed on a concentric circle. Magnitude of power supplied to arc-shaped portions of the lamps 41 can be independently adjusted, and radial distribution of a heating amount for the wafer can be adjusted.

An exhaust plate 30 is provided between the processing chamber 2 and the exhaust chamber 3 in a manner of surrounding the sample stage 4. The exhaust plate 30 is made of, for example, a ceramic material. The exhaust plate 30 has a ring shape. A central axis of the exhaust plate 30 is disposed at a position that is coaxial or approximately coaxial with a central axis of the sample stage 4.

A plurality of through holes 31 are formed in the exhaust plate 30 such that the processing chamber 2 and the exhaust chamber 3 communicate with each other. An electrode EL2 is attached to an upper surface of the exhaust plate 30. The electrode EL2 has a ring shape coaxial with the exhaust plate 30. The alumite processing is performed on a surface of the electrode EL2 to prevent the electrode EL2 from being directly exposed to the plasma PZ. The electrode EL2 may also be incorporated in the exhaust plate 30. In this case, the alumite processing may not be performed.

A vacuum pump 15 for depressurizing the inside of the vacuum container 101 is provided outside the vacuum container 101 and below the exhaust chamber 3. The vacuum pump 15 is connected to the exhaust port 13 via a pressure adjusting valve 14. By the pressure adjusting valve 14, a cross-sectional area of an exhaust path is increased or decreased, and an exhaust amount or an exhaust speed is adjusted.

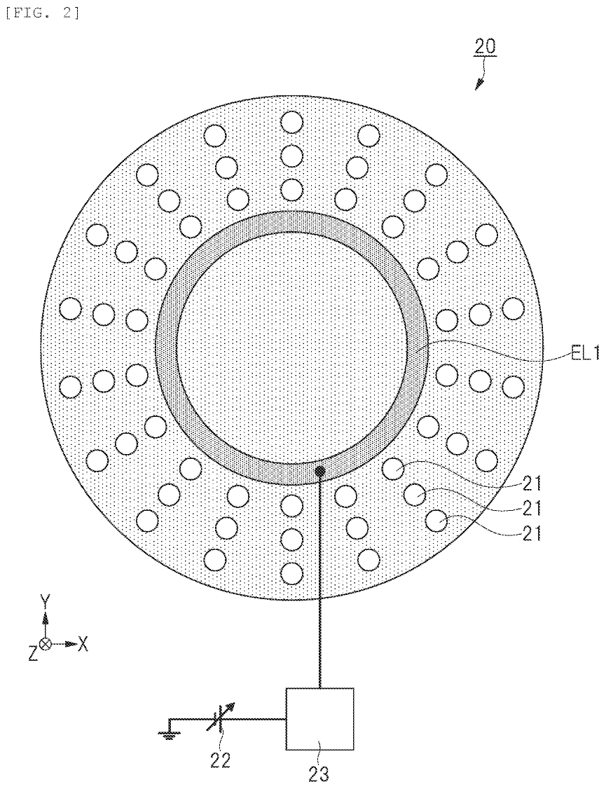

Hereinafter, a configuration of the dispersion plate 20 will be described in detail with reference to FIG. 2.

As illustrated in FIG. 2, the plurality of through holes 21 disposed in a concentric circular shape are formed in the dispersion plate 20. The plasma PZ includes ions, electrons, neutral particles, and radicals. The dispersion plate 20 is mainly provided to reduce ions and electrons introduced into the processing chamber 2. The radicals pass through the plurality of through holes 21 and are introduced into the processing chamber 2. By the disposition of the plurality of through holes 21, distribution of the radicals introduced into the processing chamber 2 is determined, and uniformity within a surface of the wafer in etching processing is adjusted.

As described in detail later, not only the radicals but also a part of the plurality of ions included in the plasma PZ pass through the plurality of through holes 21.

The electrode EL1 has a ring-shaped structure coaxial with the dispersion plate 20 and is attached to the lower surface of the dispersion plate 20. The electrode EL1 is electrically connected to a variable DC power supply 22 via a radio-frequency cut filter 23. The radio-frequency cut filter 23 is provided to prevent the noise of the radio-frequency power applied to the ICP coil 6 from flowing into the electrode EL1. A voltage range of the variable DC power supply 22 varies depending on conditions of the etching processing or a chamber structure, and is, for example, 1000 V or more and 2000 V or less.

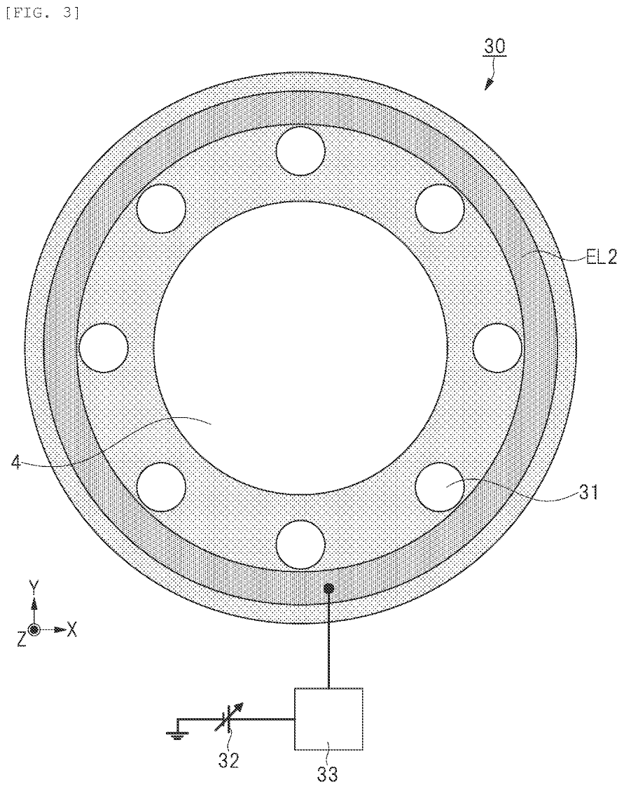

Hereinafter, a configuration of the exhaust plate 30 will be described in detail with reference to FIG. 3.

As illustrated in FIG. 3, the exhaust plate 30 is disposed between an outer circumferential side wall of the sample stage 4 and an inner circumferential side wall of the processing chamber 2. The plurality of through holes 31 disposed in a concentric circular shape are formed in the exhaust plate 30. Gas (ions, radicals, or the like) inside the processing chamber 2 is designed to be substantially uniformly exhausted to the exhaust chamber 3 through the plurality of through holes 31.

The electrode EL2 has a ring-shaped structure coaxial with the exhaust plate 30 and is attached to the upper surface of the exhaust plate 30. The electrode EL2 is electrically connected to a variable DC power supply 32 via a radio-frequency cut filter 33. The radio-frequency cut filter 33 is provided to prevent the noise of the radio-frequency power applied to the ICP coil 6 from flowing into the electrode EL2. A voltage range of the variable DC power supply 32 is, for example, 1000 V or more and 2000 V or less.

The plurality of through holes 21 are located closer to an outer periphery of the dispersion plate 20 than the electrode EL1, and the electrode EL2 is located closer to an outer periphery of the exhaust plate 30 than the plurality of through holes 31. With such a disposition, trajectories of ions passing through the plurality of through holes 21 are bent by electric field lines generated from the electrode EL1 toward the electrode EL2. Accordingly, the ions are less likely to reach the sample stage 4 and are guided to pass through the plurality of through holes 31.

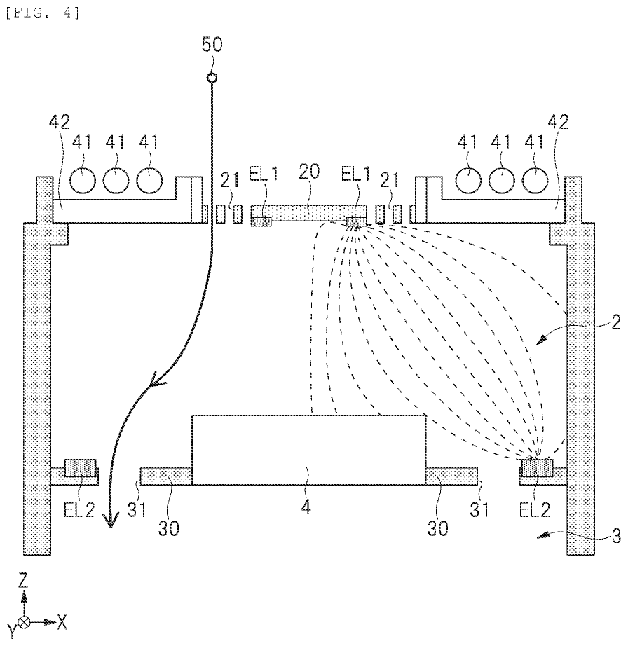

Hereinafter, a method for deviating a trajectory of ions 50 passing through the dispersion plate 20 from the inside of the surface of the wafer will be described with reference to FIG. 4. In FIG. 4, for easy understanding, the electric field lines generated between the electrode EL1 and the electrode EL2 are indicated by broken lines on a right side in FIG. 4, and the trajectory of the ions 50 is illustrated on a left side in FIG. 4.

When the wafer is placed on the sample stage 4 and the plasma PZ is emitted to the wafer, the processing gas is supplied from the processing gas supply unit 11 into the discharge chamber 1. Microwaves are output from the radio-frequency power supply 8 such that the plasma PZ is generated inside the discharge chamber 1 by the ICP coil 6. The processing gas is excited by the plasma PZ, and the inside of the discharge chamber 1 is filled with the ions, the electrons, the neutral particles, and the radicals.

Among a plurality of radicals included in the plasma PZ, radicals passing through the plurality of through holes 21 are adsorbed into a film on the surface of the wafer. A reaction layer is formed on a surface of the film by a chemical reaction between a material forming the film and the radicals. A voltage is applied from the lamp power supply 43 to the lamps 41 such that the wafer is heated by the lamps 41. Thermal energy is applied to the surface of the wafer to heat the reaction layer such that the reaction layer is desorbed from the film. Such processing is periodically repeated, so that isotropic etching processing can be selectively performed on the film.

Most of the plurality of ions included in the plasma PZ are blocked by the dispersion plate 20, but the ions cannot be completely blocked only by the dispersion plate 20. A part of the ions 50 pass through the plurality of through holes 21 and enter the inside of the processing chamber 2.

However, in Embodiment 1, when the plasma PZ is emitted to the wafer, the electric field lines are generated between the electrode EL1 and the electrode EL2. The electric field lines are formed symmetrically around the central axis of the sample stage 4 in a manner of being widened from the lower surface of the dispersion plate 20 toward the sample stage 4, and are formed with a strength distribution which is, or approximate to an extent of being regarded as, uniform in a circumferential direction. Similarly, the trajectory of the ions 50 incident into the processing chamber 2 widens symmetrically around the central axis of the sample stage 4.

That is, the ions 50 passing through the plurality of through holes 21 have the trajectory thereof bent by the electric field lines, pass through the plurality of through holes 31, enter the inside of the exhaust chamber 3, and are discharged from the exhaust port 13 to the outside of the vacuum container 101. In this manner, the ions 50 passing through the plurality of through holes 21 do not reach the wafer.

Since the radicals that are present inside the processing chamber 2 are not affected by an effect of the electric field lines, the etching processing by the radicals is not affected. In addition, wafer misalignment due to accumulation of charges described in PTL 2 can also be eliminated.

In this manner, according to Embodiment 1, it is possible to prevent the ions from reaching the sample stage without affecting the distribution and supply amount of the radicals. Therefore, it is possible to solve problems that the ions are non-uniformly incident on the wafer placed on the sample stage 4 and that the uniformity within the surface of the wafer in the etching processing decreases.

Although the invention has been specifically described based on the above embodiment, the invention is not limited to the above embodiment, and various modifications can be made without departing from the gist of the invention.

### REFERENCE SIGNS LIST

100: plasma processing apparatus
101: vacuum container
1: discharge chamber
2: processing chamber
3: exhaust chamber
4: sample stage
5: ceramic chamber
6: ICP coil
7: matching device
8: radio-frequency power supply
9: gas dispersion plate
10: top plate
11: processing gas supply unit
12: mass flow controller
13: exhaust port
14: pressure adjusting valve
15: vacuum pump
20: dispersion plate
21: through hole
22: variable DC power supply
23: radio-frequency cut filter
30: exhaust plate
31: through hole
32: variable DC power supply
33: radio-frequency cut filter
40: IR lamp unit
41: lamp
42: light transmission window
43: lamp power supply
44: radio-frequency cut filter
50: ion
EL1, EL2: electrode
PZ: plasma

1. A plasma processing apparatus comprising:
a vacuum container;
a processing chamber that is a part of an inside of the vacuum container;
a discharge chamber that is a part of the inside of the vacuum container, is provided above the processing chamber, and is configured to generate plasma;
an exhaust chamber that is a part of the inside of the vacuum container, is provided below the processing chamber, and is formed with an exhaust port;
a sample stage that is disposed inside the processing chamber and on which a wafer is placeable;
a dispersion plate provided between the processing chamber and the discharge chamber;
a plurality of first through holes formed on the dispersion plate such that the processing chamber and the discharge chamber communicate with each other;
an exhaust plate provided between the processing chamber and the exhaust chamber in a manner of surrounding the sample stage; and
a plurality of second through holes formed on the exhaust plate such that the processing chamber and the exhaust chamber communicate with each other, wherein
a first electrode having a ring shape is attached to the dispersion plate,
a second electrode having a ring shape is attached to the exhaust plate,
the first electrode is electrically connected to a first variable DC power supply, and
the second electrode is electrically connected to a second variable DC power supply.

2. The plasma processing apparatus according to claim 1, wherein
the first electrode is attached to a lower surface of the dispersion plate, and
the second electrode is attached to an upper surface of the exhaust plate.

3. The plasma processing apparatus according to claim 2, wherein
the plurality of first through holes are located closer to an outer periphery of the dispersion plate than the first electrode, and
the second electrode is located closer to an outer periphery of the exhaust plate than the plurality of second through holes.

4. The plasma processing apparatus according to claim 3, wherein
an electric field line is generated between the first electrode and the second electrode when the wafer is placed on the sample stage and the plasma is emitted to the wafer.

5. The plasma processing apparatus according to claim 4, wherein
among a plurality of ions included in the plasma, ions passing through the plurality of first through holes have a trajectory thereof bent by the electric field line, pass through the plurality of second through holes, and enter an inside of the exhaust chamber.

6. The plasma processing apparatus according to claim 5, wherein
the ions passing through the plurality of first through holes do not reach the wafer.

7. The plasma processing apparatus according to claim 5, further comprising:
a lamp provided above the sample stage and configured to heat the wafer, wherein
among a plurality of radicals included in the plasma, radicals passing through the plurality of first through holes are adsorbed into a film on a surface of the wafer,
a reaction layer is formed on a surface of the film by a chemical reaction between a material forming the film and the radicals, and
the reaction layer is heated such that the reaction layer is desorbed from the film.
